(19) United States
(12) Patent Application Publication
(10) Pub. No.: US 2026/0136724 A1
(43) Pub. Date: May 14, 2026

(54) COLOR CONVERSION MEMBER FOR LEDS

(71) Applicant: ROOTS Co., Ltd., Incheon (KR)

(72) Inventors: Sung Yoon LEE, Incheon (KR); Taek Gi LIM, Hwaseong-si (KR); Soon Min KIM, Incheon (KR); Jong Woo HA, Seoul (KR)

(73) Assignee: ROOTS Co., Ltd., Incheon (KR)

(21) Appl. No.: 18/957,964

(22) Filed: Nov. 25, 2024

(30) Foreign Application Priority Data
Nov. 12, 2024 (KR) 10-2024-0160121

(51) Int. Cl. H10H 20/851; H10H 20/856

(52) U.S. Cl. CPC H10H 20/8514; H10H 20/856

(57) ABSTRACT

The color conversion member for LEDs according to an embodiment of the present invention includes: a color conversion portion, formed in a plate shape, that converts and transmits the color of light emitted from the LED; a light reflection portion, formed to cover the side of the color conversion portion and reflect light traveling toward the side of the color conversion portion; and a light absorption portion, formed around the outer edge of the light reflection portion to cover it and absorb light that passes through the light reflection portion. The color conversion portion, the light reflection portion, and light absorption portion are integrally formed into a plate shape with a flat light-emitting surface, wherein the light reflection portion reflects light traveling toward the side of the color conversion portion, and the light absorption portion eliminates side-traveling light, thereby enhancing the straightness of the emitted light.

### CROSS-REFERENCE TO RELATED APPLICATION

This application claims priority to and the benefit of Korean Patent Application No. 10-2024-0160121, filed on November 12, 2024, the disclosure of which is incorporated herein by reference in its entirety.

### BACKGROUND

### 1. Field of the Invention

The present disclosure relates to a color conversion member for an LED. More specifically, the present disclosure relates to a color conversion member for an LED that is installed in front of an LED chip and changes the wavelength of light emitted from the LED.

### 2. Discussion of Related Art

Applications that multiple small LEDs are arranged and control them to turn on and off independently, such as multi-beam LEDs for automotive headlights, have been increased. Since each small LED is independently illuminated, it is essential to enhance the light straightness and light quality of each LED.

Japanese Patent No. 7117127 discloses a light-emitting device comprising a substrate, a light-emitting element implemented on the substrate, and a wavelength conversion member (17) disposed on the light-emitting element with a bottom surface covering the entire top surface of the light-emitting element and a top surface smaller than the bottom. The wavelength conversion member has side surfaces that narrow in width toward the top surface from the bottom. Additionally, a first covering member (19) covers the side surface of the wavelength conversion member, while a second covering member (21) covers the entire side surface of the light-emitting element and extends from the periphery of the bottom surface of the wavelength conversion member toward the top surface. The first and second covering members possess different light absorption rates, with the first covering member filling the space between the second covering member and the wavelength conversion member. The inner surface of the second covering member extends vertically from the periphery of the bottom surface of the wavelength conversion member toward the top surface, providing a light-emitting device with enhanced optical performance.

### SUMMARY OF THE INVENTION

The present disclosure is directed to providing a color conversion member for LEDs with high light straightness, a smooth surface, and a compact size without cracks or chipping, thereby enhancing the light quality of LEDs.

The color conversion member for LEDs according to an embodiment of the present invention comprises: a color conversion portion, formed in a plate shape, that converts and transmits the color of light emitted from the LED; a light reflection portion, formed to cover the side of the color conversion portion and reflect light traveling toward the side of the color conversion portion; and a light absorption portion, formed around the outer edge of the light reflection portion to cover it and absorb light that passes through the light reflection portion. The color conversion portion, the light reflection portion, and light absorption portion are integrally formed into a plate shape with a flat light-emitting surface. The light reflection portion reflects light traveling toward the side of the color conversion portion, and the light absorption portion eliminates side-traveling light, thereby enhancing the straightness of the emitted light.

The side of the color conversion portion is formed with an inclined surface, the light reflection portion is shaped as a layer to cover the inclined side of the color conversion portion, and the light absorption portion is formed in a rectangular frame shape with its inner surface inclined and its outer surface parallel to the light direction. Thus, the overall structure can have a rectangular flat-plate shape.

The side of the color conversion portion is inclined up to a certain depth, with the remaining portion formed parallel to the light propagation direction. The light reflection portion is plate-shaped, covering the side of the color conversion portion, and similarly, part of it is inclined to the light propagation direction, while another part runs parallel. The light absorption portion is formed in a rectangular frame shape, with part of the inner side inclined and the remaining part aligned parallel to the light propagation direction, while the outer side is formed parallel to the light propagation direction, allowing the entire structure to take on a rectangular flat-plate shape.

The light reflection portion can be made of a material selected from aluminum, silver, gold, copper, chromium, titanium dioxide, or cerium oxide, and it can be attached to the color conversion portion by a deposition method, forming a thin layer.

The light absorption portion can be a mixture of glass and carbon powder, created by mixing liquid glass with carbon powder and then curing it.

The light absorption portion can be chromium oxide or a nickel-chromium alloy, deposited on the outside of the light reflection portion.

### BRIEF DESCRIPTION OF THE DRAWINGS

The above and other objects, features and advantages of the present disclosure will become more apparent to those of ordinary skill in the art by describing exemplary embodiments thereof in detail with reference to the accompanying drawings, in which:

FIG. 1 is a cross-sectional view of a color conversion member for LEDs according to an embodiment of the present invention;

FIGS. 2 to 5 shows the direction of light propagation and light quality when using a color conversion member for LEDs according to a comparative example of the present invention;

FIG. 6 is a diagram showing the method of manufacturing a color conversion member for LEDs according to an embodiment of the present invention;

FIGS. 7 to 15 shows the results of processes in the method of manufacturing a color conversion member for LEDs of the present invention;

FIG. 16 is a perspective view of a color conversion member for LEDs according to an embodiment of the present invention;

FIG. 17 is a cross-sectional view of a color conversion member for LEDs according to another embodiment of the present invention.

### DETAILED DESCRIPTION OF EXEMPLARY EMBODIMENTS

Hereinafter, embodiments of the present disclosure will be described with reference to the accompanying drawings. The accompanying drawings show exemplary forms of the present disclosure, which are only provided to describe the present disclosure in more detail, and the technical scope of the present disclosure is not limited thereto.

In addition, regardless of reference numerals, the same or corresponding components are given the same reference numerals, and overlapping description thereof will be omitted, and for convenience of description, the sizes and shapes of each component member shown may be exaggerated or reduced.

Meanwhile, terms including ordinal numbers, such as first, second, etc., may be used to describe various components, but the components are not limited by the terms, and the terms are only used for the purpose of distinguishing one component from another.

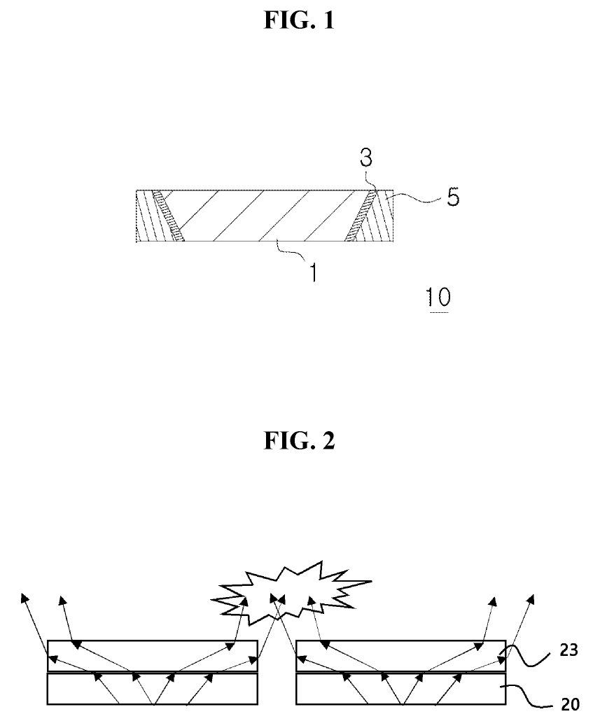

The color conversion member for LEDs 10, according to an embodiment of the present invention, as shown in FIG. 1, can be formed in a flat-plate shape. A color conversion portion 1 is formed at the central part, with a light reflection portion 3 surrounding it. Around the periphery of the light reflection portion 3, a light absorption portion 5 can be formed.

The color conversion portion 1 is shaped as a rectangular plate with sloped sides. The light reflection portion 3 can be formed on the outer side of these sloped sides. The light reflection portion 3 can be in contact with the sides of the color conversion portion 1, with its outer surface formed parallel to the inner surface. The light reflection portion 3 can be configured to cover the entire side of the color conversion portion 1.

The light absorption portion 5 can be formed to adhere to the outer surface of the light reflection portion 3. The inner surface of the light absorption portion 5 can be shaped with a slope same to the outer surface of the light reflection portion 3. The outer surface of the light absorption portion 5 can be oriented perpendicular to the upper and lower surfaces of the color conversion portion 1. The light absorption portion 5 can have a rectangular frame shape that covers the side of the light reflection portion 3. In the combined state, the color conversion portion 1, a light reflection portion 3, and light absorption portion 5 form the color conversion member 10, which can be shaped as a flat rectangular plate.

The color conversion portion 1 can be manufactured by mixing fluorescent material powder, glass powder, and a binder, followed by sintering. The light reflection portion 3 can be a thin plate or layer or film made of a metal such as aluminum, silver, gold, copper, chromium, titanium dioxide, or cerium oxide. The light absorption portion 5 can be produced by mixing carbon powder with a silicone resin or epoxy resin. Liquid glass may also be used in place of silicone resin, which can offer advantages in terms of strength, durability, and adhesive force compared to silicone resin. As light passes through the color conversion portion 1, its color is modified; upon encountering the light reflection portion 3, it is reflected, and upon encountering the light absorption portion 5, it is absorbed.

As shown in FIG. 2, a color conversion member 23 can be attached to the emission surface of an LED chip 20, forming a light-emitting module. The LED chip 20 emits blue light, which is converted to white light as it passes through the color conversion member 23 and is then emitted. However, in a comparative example where the color conversion member 23 consists only of a color conversion portion 1, the light does not travel in a straight line during the color conversion process. Specifically, the light does not proceed perpendicularly to the surface of the color conversion member 23 but instead spreads laterally, as shown in FIG. 2. By arranging multiple light-emitting modules and independently controlling their on-off states, light can be directed to radiate only in desired directions. If, however, the straightness of each light-emitting module is reduced, it becomes impossible to direct light only in the intended direction. As shown in FIG. 2, the light emitted by adjacent light-emitting modules may overlap and interfere with each other, potentially reducing resolution.

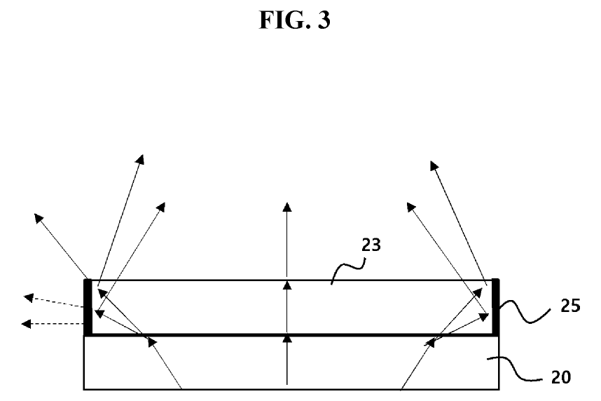

As shown in FIG. 3, a light reflection portion 25 can be formed in a thin plate or film or layer around the side of the color conversion member 23. However, even in this case, the light may not proceed in a straight path, with some reflected light traveling in the opposite direction due to the light reflection portion 25. In such cases, the straightness of the light may still decrease. While some of the light emitted from the LED chip 20 may travel in a straight path, some may proceed towards the side of the color conversion member 23, requiring correction to ensure that the side-directed light also moves in a straight line. As shown in FIG. 3, not all light reaching the light reflection portion 25 is reflected; some light may pass through the light reflection portion 25. Theoretically, the light reflection portion 3 should reflect all light; however, when implemented in an actual product, a significant portion is reflected, but some light may pass through the light reflection portion 25 and proceed sideways. Consequently, this may lead to reduced straightness and contrast.

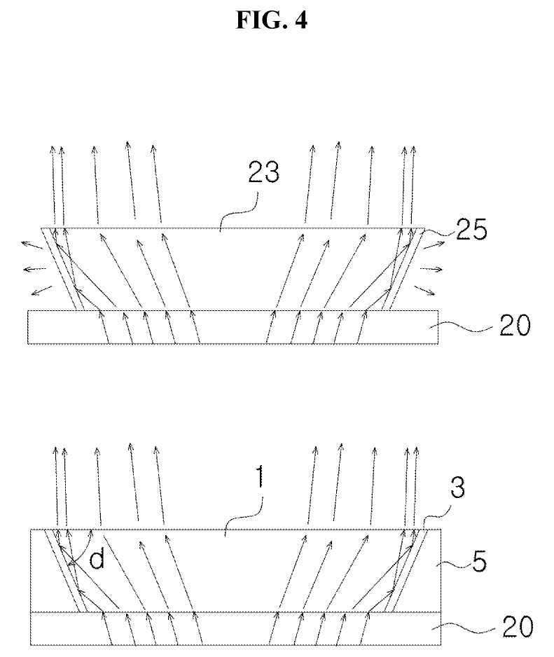

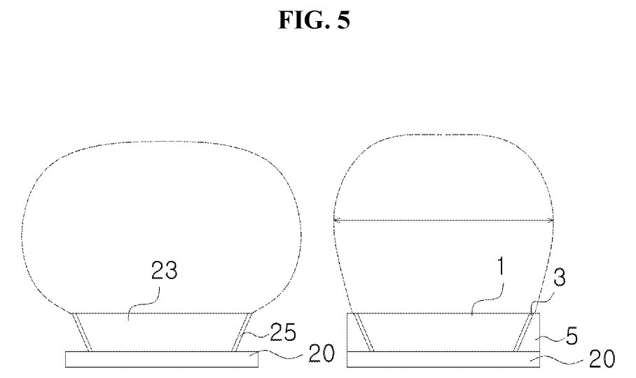

As shown in FIGS. 4 and 5, the color conversion member 10 according to the embodiment of the present invention is configured such that the area of the color conversion portion 1 gradually increases along the direction of light propagation. Similarly, the light reflection portion 3, which covers the side of the color conversion portion 1, is also formed to expand its inner area along the direction of light propagation. By configuring the reflection surface to widen in the light propagation direction, light traveling towards the side of the color conversion member 10 is reflected by the light reflection portion 3 toward the center, thereby enhancing straightness. Additionally, since all light passing through the light reflection portion 3 is absorbed by the light absorption portion 5, only light traveling in a straight line is converted and emitted. Here, the direction of light propagation refers to the direction orthogonal to the surface of the LED chip 20, representing the ideal direction toward which all light components are directed when optimal straightness is achieved.

Accordingly, as shown in FIG. 5, the radiation pattern of light according to the embodiment of the present invention can be formed with a narrower width compared to the radiation pattern of light in the comparative example. Such a light-emitting module with good light straightness is useful when multiple light-emitting modules are arranged to face different positions and controlled to emit lights only to desired locations.

The color conversion member for LEDs 10 integrates the light reflection portion 3 and the light absorption portion 5 within itself. A light-emitting module may also be configured by attaching a color conversion member 23 with only a color conversion portion 1 on the LED chip 20, and separately installing a light reflection or light absorption component on its side. However, in applications with severe vibrations, such as in automotive headlights, gaps may form, or components may detach if the light reflection or absorption components are not tightly adhered to the color conversion member 23. Thus, by forming the light reflection portion 3 and the light absorption portion 5 integrally within the color conversion member 10 itself, optical straightness can be maintained for extended periods even under harsh conditions. Moreover, as there is no need to construct a separate light absorption wall for the color conversion member 10, the design freedom is enhanced, and material use is minimized. Along with vibration, temperature also affects the durability of the light-emitting module. Given the high power during headlight operation, the internal temperature of the light-emitting module can rise to 200°C, while it may drop to -40°C during parking in winter. In such cases, thermal expansion and contraction of the various components can lead to cracks if gaps exist between them. These cracks degrade the optical quality of the light-emitting module. The color conversion member 10 according to the embodiment of the present invention, with its integrated and solidly adhered a light reflection portion 3 and light absorption portion 5, prevents quality degradation caused by temperature variation and vibration.

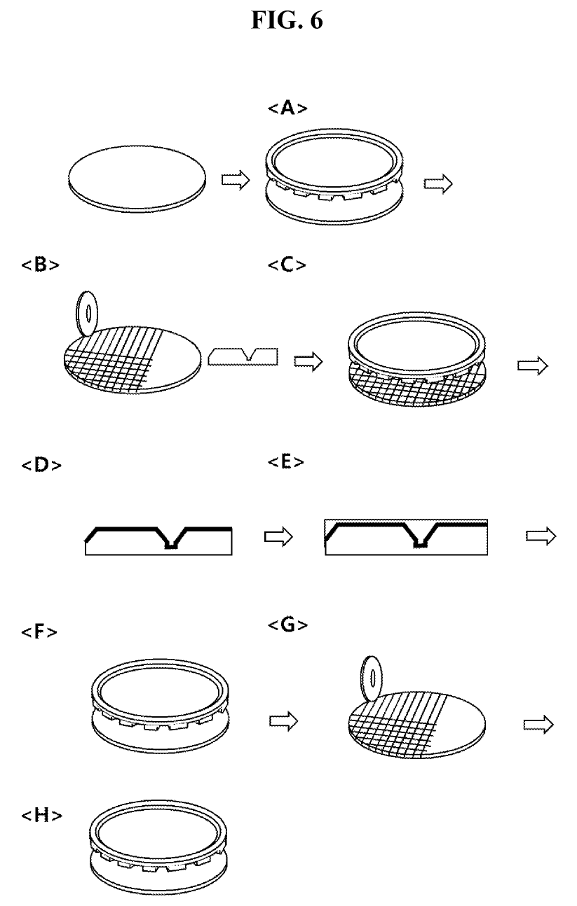

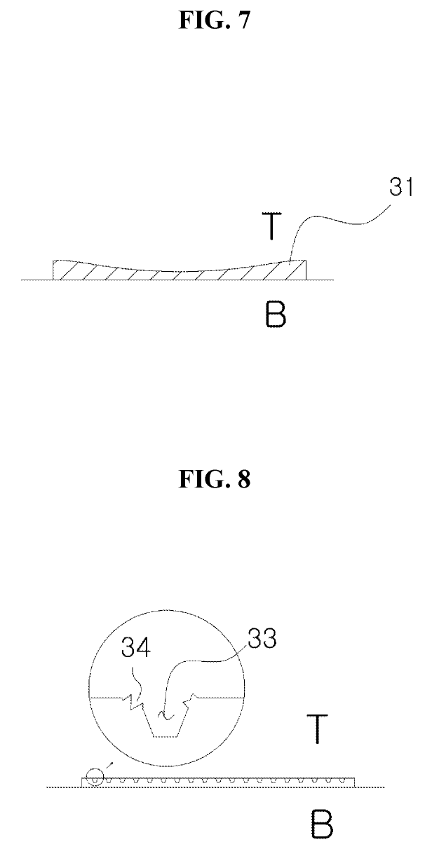

The color conversion member for LEDs 10 according to an embodiment of the present invention can be manufactured through the process shown in FIG. 6. As shown in FIG. 7, a wafer 31, which will be divided into individual color conversion members for LEDs 10, is first prepared. The wafer 31 may be manufactured in a circular or square shape. It is more efficient to manufacture a large wafer 31 and divide it into small chip-sized color conversion members for LEDs 10 than to manufacture small color conversion members for LEDs 10 at the actual product size from the beginning. This approach is used because the size of the color conversion members for LEDs 10 typically in use is relatively small for manual or machine processing. The wafer 31 can be obtained by mixing powdered phosphor with glass crystals or silicone resin, followed by sintering, compression, and drying processes.

Since this wafer 31 is not of the size required for application in actual products, it must be separated into smaller color conversion members for LEDs 10. Additionally, as its surface may be rough or curved, it requires a planarization process.

As shown in FIG. 6, in process <A>, the upper surface of the wafer 31 is ground. The wafer 31 prepared as shown in FIG. 7 has a flat bottom surface B, but its top surface T may be uneven or sloped. It is common for the center to be thin and the outer edges thick, giving the top surface T a curved shape. In process <A>, grinding the top surface T with a grinder flattens it. If there are slight irregularities left on the top surface T—that is, if the surface roughness has not reached the desired level—a fine grinding process can be repeated to smooth it further.

The grinding operation can be performed using a surface grinder, which removes the wafer 31’s surface as a wide, disk-shaped disc rotates. Through grinding, the thickness of the wafer 31 gradually and uniformly decreases. A grinding system may include mechanical equipment with a support that can move the grinder, a support bed for holding the wafer 31, and a control unit.

Next, in process <B>, dicing trenches 33 are formed in the wafer 31. Multiple dicing lines are formed in straight lines at regular intervals using a dicing blade, followed by perpendicular dicing lines to create a grid pattern. By cutting only to a partial depth, without completely dividing the wafer 31, the dicing trenches 33 can be formed. Between the dicing trenches 33, the wafer 31 remains raised, forming sections that will later become individual color conversion members 10 for LEDs.

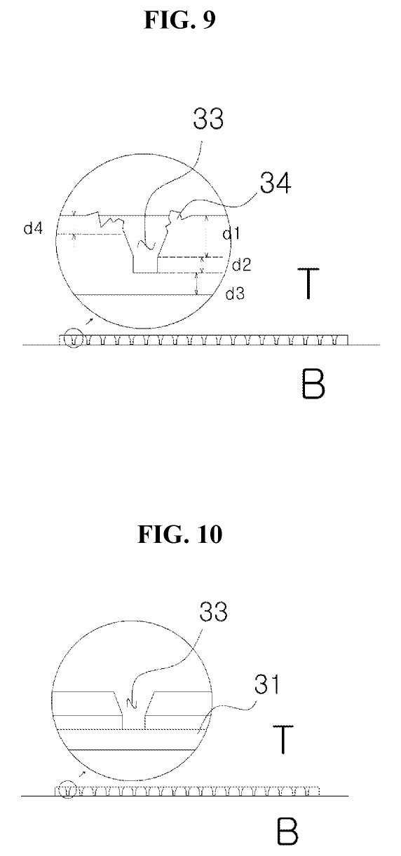

A bevel-type dicing blade with a gradually narrowing width toward the outside may be utilized. As shown in FIG. 8, the width of the dicing trench 33 also gradually widens outward. Then, the bottom surface of the dicing trench 33 is cut again. This time, a planar dicing blade without an inclined edge, unlike the bevel-type dicing blade with sloped sides, is used. In the first cutting process, the bevel-type dicing blade has its narrowest width at the outermost edge relative to its center of rotation. A dicing blade with the same or slightly larger width than this can be used for the second cutting. As shown in FIG. 9, the dicing trench 33 is completed after the first and second cuts.

The dicing trench 33 is formed to a certain depth d1 by the first cut, and the next depth d2 is formed by the second cut. The bottom surface of the dicing trench 33 is separated by a specified thickness d3 from the base surface. The section formed by the first cut is sloped to gradually narrow in width, while the section formed by the second cut below it has a constant width.

As shown in FIG. 9, chipping areas 34 are formed along with the formation of the dicing trench 33. During the process of cutting wafer 31 with the dicing blade, the wafer surface may chip, resulting in a rough finish. The wafer 31 is created by combining various particles, and thus, as the surface is cut with the dicing blade, the materials constituting the wafer 31 chip away, forming the dicing trench 33 while simultaneously causing chipping. This chipping phenomenon commonly occurs around the edges of the dicing trench 33, particularly at the outermost edges. A chipping area 34 may form at the widest outer edge of the top of the dicing trench 33. It is recommended to remove this to achieve a smooth surface.

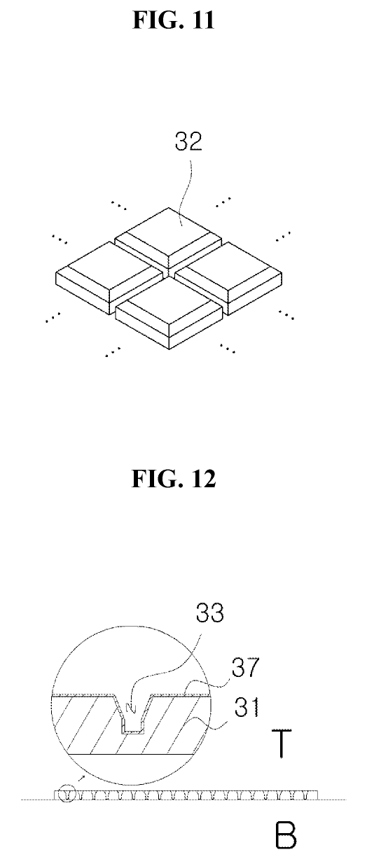

Referring to FIGS. 6, 9, and 10, in process <C>, the top surface T of wafer 31, where dicing trenches 33 are formed, is ground using a surface grinder. This process ensures that the thickness of wafer 31 is uniformly reduced. By performing grinding, chipping areas 34 can be removed. Since the grinding aims to remove the chipping areas 34, it is conducted only to a specified depth d4 on the surface area to avoid completely removing the sloped surface formed during the first cut, process <B>. Upon completing process <C>, wafer 31, as shown in FIGS. 10 and 11, is obtained with protrusions 32 in a decahedral shape arranged in a matrix pattern on the surface. The upper side surfaces of the protrusions 32 are sloped, while the lower side surfaces are formed vertically.

As shown in FIGS. 6 and 12, in process <D>, a reflective layer 37 is formed on the surface of wafer 31. The reflective layer 37 can be created in a layer form covering the surface of color conversion member 10. The reflective layer 37 may be formed through a layer deposition method. Using this approach, wafer 31 is secured within a vacuum chamber with the surface containing dicing trenches 33 facing downward. Metal placed below is evaporated, condensing on the surface of wafer 31 until a predetermined thickness is achieved. By depositing reflective layer 37 onto the surface of wafer 31 where dicing trenches 33 are formed, as shown in FIG. 12, reflective layer 37 extends into the interiors of dicing trenches 33. This reflective layer 37 ultimately forms the light reflection portion 3 of the finished color conversion member 10.

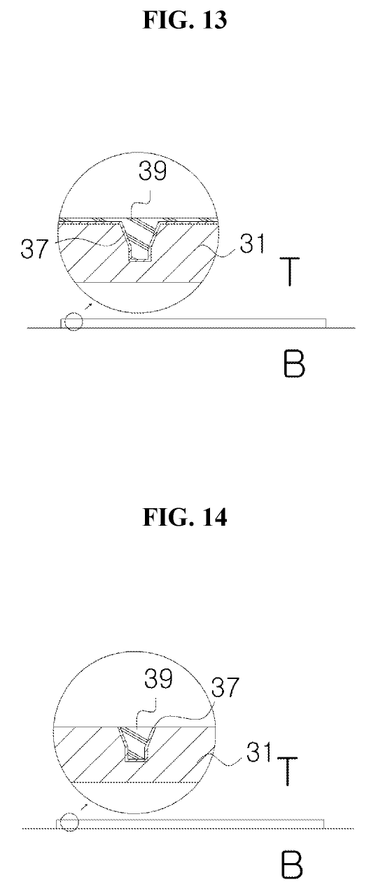

As shown in FIGS. 6 and 13, in process <E>, a light-absorbing material 39 is applied to the surface T of wafer 31 where dicing trenches 33 are formed. A light-absorbing material 39 with fluidity can be created by mixing carbon powder with silicone resin or epoxy resin, and this material can be applied to cover the entire surface of wafer 31, including the interiors of dicing trenches 33. This application can then be dried at room temperature or through heat drying to allow light-absorbing material 39 to adhere to the outer surface of reflective layer 37. Light-absorbing material 39 ultimately forms the light absorption portion 5 of the final processed color conversion member 10. After applying light-absorbing material 39, it may be leveled with a scraper and then dried. Consequently, light-absorbing material 39 can be uniformly filled within dicing trenches 33.

A method of applying the light-absorbing material 39 could involve injecting a mixture of carbon with silicone resin or liquid glass into dicing trenches 33; however, other methods may also be used to apply light-absorbing material 39. Similar to forming the reflective layer 37 via deposition, light-absorbing material 39 can also be coated or deposited onto wafer 31. In this case, the light-absorbing material 39 used may be chromium oxide or a nickel-chromium alloy.

As shown in FIGS. 6 and 14, in process <F>, the surface of wafer 31, where light-absorbing material 39 is fixed, is ground. This results in the light-absorbing material 39 on the surface of wafer 31 being uniformly ground down to a consistent thickness. As shown in FIG. 14, grinding can continue until the top surfaces of the protrusions 32 of wafer 31 are exposed. There is no need to grind too deeply, reaching the deeper sections of dicing trenches 33. Through this grinding process, the top surface of wafer 31 is exposed, and the dicing trenches 33 are filled with reflective layer 37 and light-absorbing material 39. Instead of attaching the reflective layer 37 or light-absorbing material 39 to the sides after making color conversion member 10, the reflective layer 37 and light-absorbing material 39 are integrated into wafer 31 by filling the dicing trenches 33. As a result, wafer 31, reflective layer 37, and light-absorbing material 39 can be tightly unified.

Although it is possible to create the state shown in FIG. 14 by filling only the dicing trenches 33 with light-absorbing material 39, it is preferable, as shown in FIG. 13, to apply the light-absorbing material 39 over both the upper surface of wafer 31 and dicing trenches 33, then grind it down. This is because it is practically impossible to fill only the dicing trenches 33 cleanly, precisely, and uniformly with light-absorbing material 39. Similarly, it is challenging to deposit reflective layer 37 accurately only within dicing trenches 33. Therefore, reflective layer 37 and light-absorbing material 39 are uniformly applied over the entire surface of wafer 31, including the dicing trench 33 areas, and then ground to expose the areas outside of dicing trenches 33. This method ensures that reflective layer 37 and light-absorbing material 39 are securely adhered to wafer 31 and uniformly fill the entire dicing trench 33 structure.

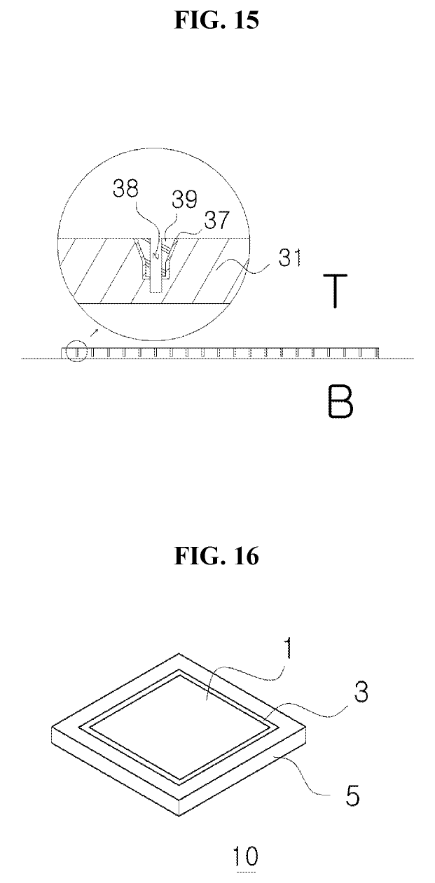

As shown in FIGS. 6 and 15, in process <G>, additional dicing trenches 38 are formed on the surface of wafer 31, where light-absorbing material 39 and reflective layer 37 are filled. This process is similar to process <B> in that dicing trenches 38 are formed using a dicing blade. The location for forming the new dicing trenches 38, as shown in FIG. 15, is where the original dicing trenches 33 were filled with reflective layer 37 and light-absorbing material 39. Following the same dicing lines as the initial dicing trenches 33, secondary dicing trenches 38 are formed. A very thin dicing blade is used, resulting in the formation of very narrow dicing trenches 38. The dicing trenches 38 are positioned to cut through the light-absorbing material 39, splitting it down the middle, but not reaching the sides of reflective layer 37 due to the narrow width of the dicing trenches. The width of dicing trenches 38 can be narrower than the shortest distance between the sides of adjacent reflective layers 37. The sidewalls of dicing trenches 38 consist of light-absorbing material 39, with reflective layer 37 and color conversion portion 1 located inside.

The depth of the secondary dicing trenches 38 can be deeper than that of the primary dicing trenches 33. However, it is not deep enough to cut completely through wafer 31. Therefore, in process <G>, wafer 31 is not entirely separated into individual color conversion members 10. The complete separation of wafer 31 into color conversion members 10 occurs in process <H>. It is possible to complete the cutting in process <G> using the dicing blade. However, this may result in uneven or slanted sides on the color conversion member 10, as the rotational force of the high-speed dicing blade can cause unintended movement or ejection of color conversion members 10. In the worst case, parts of the light absorption material 39 may break off, or the reflective layer 37 may be damaged. To obtain a clean and smooth color conversion member 10, only dicing trenches 38 are formed in process <G>, and wafer 31 is finally separated into multiple color conversion members 10 in process <H>.

In this embodiment, the method describes conducting process <G> after process <F>, but alternatively, it is also possible to perform process <G> first, followed by process <F>. This would involve first forming the dicing trenches 38 and then performing the grinding.

In process <H>, the wafer 31 with the secondary dicing trenches 38 formed is flipped so that the surface faces downward, and the opposite side is ground. The grinding process uniformly reduces the thickness of wafer 31. As previously described, wafer 31 has decahedral projections 32 arranged, with the spaces between projections 32 filled with the reflective layer 37 and the light absorption material 39. The sides of the decahedral projections 32 include sections parallel to the light propagation direction and sloped sections. By reducing the thickness of wafer 31 until the grinder reaches the sloped sides of projections 32, it is possible to obtain the color conversion member 10 as shown in FIGS. 1 and 16. As the grinder applies downward pressure uniformly on wafer 31, the color conversion members 10 do not deviate from their designated positions during the separation process. This results in a plurality of color conversion members 10 with smooth surfaces and securely integrated a light reflection portions 3 and light absorption portions 5 along the sides.

Attaching this color conversion member 10 to the emission surface of the LED chip 20 allows for an emission module with excellent light directivity, as shown in FIG. 4. A high-directivity emission module can be constructed using only the LED chip 20 and color conversion member 10, without additional components. This color conversion member 10 has a smooth surface on the color conversion portion 1, a uniformly thick and smooth the light reflection portion 3, and a smooth-surfaced light absorption portion 5, preventing light scattering. This structure further enhances light directivity. As shown in FIG. 3, when the surface of color conversion member 23 and the light reflection portion 25 form a right or larger angle, light directivity may decrease. However, as shown in FIG. 4, the color conversion member 10 according to this embodiment has an acute angle (d) between the light-emitting surface of the color conversion member 10 and the light reflection portion 3. In other words, the light reflection portion 3 gradually widens along the light propagation direction, enhancing light directivity.

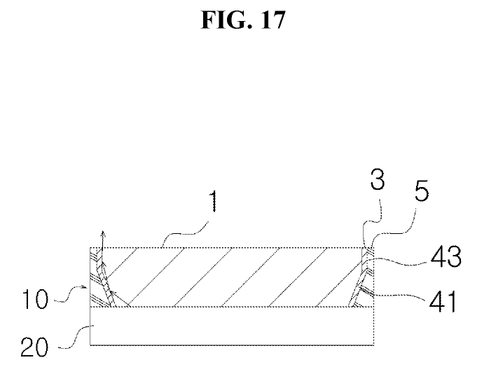

In process <H>, performing thicker grinding yields a color conversion member 10 with the cross-section shown in FIG. 1, while thinner grinding yields a color conversion member 10 with the cross-section shown in FIG. 17. In the latter case, grinding is conducted only to the extent that removes the bottom of the light reflective layer 37, rather than reaching the inclined side of the protrusion 32. As a result, the side of the color conversion portion 1, the light reflection portion 3, and the light absorption portion 5 can form a section 43 parallel to the light propagation direction and a section 41 with an inclined shape. The light reflection portion 3 near the LED chip 20 is inclined, allowing it to gather light effectively. For the light reflection portion 3 in areas farther from the LED chip 20, where fewer light components proceed laterally, it is formed parallel to the light propagation direction to guide light along a straight path rather than actively gathering it.

Meanwhile, FIGS. 1, 16, and 17 illustrate examples of a color conversion member 10 formed by injecting and securing the light absorption material 39 within the dicing trench 33. When a light absorption material 39 such as chromium oxide or a nickel-chromium alloy is coated or deposited onto the wafer 31, the light absorption material 39 may not completely fill the dicing trench 33. In such cases, the light absorption portion 5 can also form a layer similar to the light reflection portion 3. Therefore, when manufactured using the previously described process, the side of the light absorption portion 5 may not be formed perpendicularly to the light propagation direction, but rather inclined, like the light reflection portion 3, as shown in FIG. 1. Additionally, if the light absorption material 39 does not fully fill the dicing trench 33, process <G> may be omitted. If the light absorption material 39 layer is thin, it may be possible to grind the upper surface of the wafer 31 in process <F> and then proceed directly to process <H> to separate the wafer 31 into the color conversion member 10.

Meanwhile, although the above description has focused on the inclined shape of the inner surface area of the light reflection portion 3 gradually widening along the light propagation direction, the color conversion member 10 can also be installed in the opposite direction toward the LED chip 20. Even in this orientation, the light straightness can be improved compared to cases without the light reflection portion 3 or light absorption portion 5.

Although embodiments of the present disclosure have been described above, those skilled in the art may variously modify and change the present disclosure by the addition, change, or deletion, of components without departing from the spirit of the present disclosure described in the appended claims, which will also be included in the scope of the present disclosure.

What is claimed is:

1. A color conversion member for LEDs, comprising:
a color conversion portion, formed as a flat plate, configured to alter the color of light emitted from the LED as it passes through;
a light reflection portion, formed to cover the sides of the color conversion portion and configured to reflect light traveling toward the sides of the color conversion portion;
a light absorption portion, formed around the outer edge of the light reflection portion, configured to absorb light that passes through the light reflection portion;
wherein the color conversion portion, the light reflection portion, and the light absorption portion are integrally formed as a flat plate with a light emission surface, and the light reflection portion reflects light traveling toward the sides of the color conversion portion, while the light absorption portion removes side-directed light, thereby improving the straightness of the emitted light.

2. The color conversion member for LEDs of claim 1, wherein:
the side surface of the color conversion portion is formed at an incline;
the light reflection portion has a layer shape and is formed to cover the inclined side surface of the color conversion portion;
the light absorption portion is formed in a rectangular frame shape, with an inclined inner side surface and an outer side surface parallel to the direction of light propagation;
whereby the entire structure is formed in a rectangular flat plate shape.

3. The color conversion member for LEDs of claim 1, wherein:
the side surface of the color conversion portion is inclined up to a certain depth, with the remaining portion formed parallel to the direction of light propagation;
the light reflection portion has a layer shape and covers the side surface of the color conversion portion, with some portions inclined in the direction of light propagation and other portions parallel, similarly to the color conversion portion;
the light absorption portion is formed in a rectangular frame shape, with part of the inner side surface inclined and the rest formed parallel to the direction of light propagation, and the outer side surface is formed parallel to the direction of light propagation;
whereby the entire structure is formed in a rectangular flat plate shape.

4. The color conversion member for LEDs of claim 1, wherein:
the light reflection portion is made of one selected from the group consisting of aluminum, silver, gold, copper, chromium, titanium dioxide, and cerium oxide, and is attached to the color conversion portion by a deposition method in the form of a layer.

5. The color conversion member for LEDs of claim 1, wherein:
the light absorption portion is a mixture of glass and carbon powder, formed by mixing liquid glass and carbon powder and curing the mixture.

6. The color conversion member for LEDs of claim 1, wherein:
the light absorption portion is chromium oxide or a nickel-chromium alloy and is coated by a deposition method on the outside of the light reflection portion.
